(19) United States
(12) Patent Application Publication
(10) Pub. No.: US 2026/0227711 A1
(43) Pub. Date: Aug. 6, 2026

(54) EXPOSURE APPARATUS, EXPOSURE METHOD, AND METHOD FOR MANUFACTURING ARTICLE

(71) Applicant: CANON KABUSHIKI KAISHA, Tokyo (JP)

(72) Inventors: MITSURU INOSE, Ibaraki (JP); KAZUSHI MIZUMOTO, Tochigi (JP)

(21) Appl. No.: 19/444,745

(22) Filed: Jan. 9, 2026

(30) Foreign Application Priority Data
Jan. 21, 2025 (JP) 2025-008223

(51) Int. Cl. G03F 7/00

(52) U.S. Cl. CPC G03F 7/70725; G03F 7/70258; G03F 7/70508; G03F 7/706; G03F 7/70758

(57) ABSTRACT

An exposure apparatus configured to expose a pattern of a mask onto a substrate includes an illumination optical system configured to illuminate the mask, a projection optical system configured to project light from the mask onto the substrate, a rotation unit configured to rotate the mask, and a control unit configured to control the rotation unit to rotate the mask based on information regarding the projection optical system.

### BACKGROUND

### Field of the Technology

The present technique relates to an exposure apparatus, an exposure method, and a method for manufacturing an article.

### Description of the Related Art

In manufacturing processes of semiconductor devices or liquid crystal display devices, an exposure apparatus is sometimes used that exposes a pattern of a mask onto a substrate through a projection optical system. The aberration of the projection optical system varies during exposure processing, and when the aberration exceeds an allowable value, the exposure accuracy deteriorates.

Japanese Patent Laid-Open No. 2006-73584 discloses suspending the exposure process until the aberration becomes equal to or less than an allowable value.

However, in the method disclosed in Japanese Patent Laid-Open No. 2006-73584, the throughput per unit time decreases when the exposure process is suspended until the aberration becomes equal to or less than an allowable value.

### SUMMARY

The present technique provides an exposure apparatus advantageous in

terms of throughput.

According to an aspect of the present disclosure, there is provided an exposure apparatus configured to expose a pattern of a mask onto a substrate. The exposure apparatus includes an illumination optical system configured to illuminate the mask, a projection optical system configured to project light from the mask onto the substrate, a rotation unit configured to rotate the mask, and a control unit configured to control the rotation unit to rotate the mask based on information regarding the projection optical system.

Features of the present disclosure will become apparent from the following description of embodiments with reference to the attached drawings. The following description of embodiments is described by way of example.

### BRIEF DESCRIPTION OF THE DRAWINGS

FIG. 1 is a schematic diagram illustrating the configuration of an exposure apparatus according to a first embodiment.

FIG. 2 is a schematic diagram of an exposure unit according to the first embodiment.

FIGS. 3A and 3B are schematic diagrams illustrating an exposure load on an optical element included in a projection optical system when light is applied to a pattern of a mask.

FIG. 4 is a flowchart for rotating the mask based on information regarding the projection optical system.

FIGS. 5A and 5B are schematic diagrams of aberration variations in a region of an optical element included in the projection optical system that is used for exposing a substrate.

FIGS. 6A to 6C are schematic diagrams illustrating rotational angles when the mask is rotated.

FIG. 7 is a schematic diagram of an exposure unit according to a second embodiment.

FIG. 8 is a flowchart for rotating the projection optical system based on information regarding the projection optical system.

FIG. 9 is a schematic diagram of the exposure unit according to the second embodiment.

FIG. 10 is a flowchart for rotating an optical element included in the projection optical system based on information regarding the projection optical system.

FIG. 11 is a flowchart illustrating a method for manufacturing an article according to a third embodiment.

### DESCRIPTION OF THE EMBODIMENTS

Embodiments of the present technique will be described in detail

hereinbelow with reference to the accompanying drawing. It is to be understood that the following embodiments do not limit the disclosure according to the scope of the claims. Although the embodiments describe a plurality of features, not all of them are absolutely necessary, and the embodiments may also be freely combined. In the accompanying drawings, like or similar components are given like reference signs, and duplicated descriptions are omitted.

In this specification and the drawings, the vertical direction is basically defined as a Z-axis direction, and a horizontal plane perpendicular to the vertical direction is defined as an X-Y plane. Directions are indicated by an X-Y-Z coordinate system in which the individual axes are orthogonal to one another. However, when the X-Y-Z coordinate system is indicated in the drawings, the X-Y-Z coordinate system shall take precedence.

Hereinafter, specific configurations will be described in the embodiments.

### First Embodiment

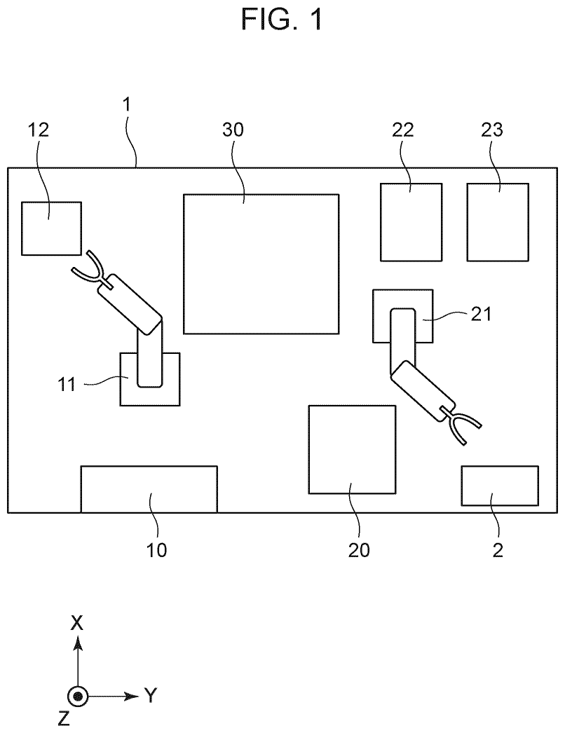

FIG. 1 is a schematic diagram illustrating the configuration of an exposure apparatus 1 according to the present embodiment. The exposure apparatus 1 according to this embodiment is an exposure apparatus that exposes a pattern of a mask or a reticle onto a substrate through a projection optical system by a step-and-repeat method or a step-and-scan method.

The exposure apparatus 1 includes a substrate loading/unloading unit 10, a substrate transfer unit 11, a pre-alignment unit 12, a mask stocker 20, a mask transfer unit 21, a mask rotation unit 22, a mask determination unit 23, an exposure unit 30, and a control unit (processing unit) 2.

A substrate loaded into the substrate loading/unloading unit 10 is conveyed by the substrate transfer unit 11 to a desired position within the exposure apparatus 1. The pre-alignment unit 12 adjusts the position (rotational angle) of the substrate in advance before the substrate is conveyed to the exposure unit 30. The mask stocker 20 stores multiple masks to be used in an exposure process. The mask transfer unit 21 includes a hand for holding the mask and conveys the mask to a desired position within the exposure apparatus 1. The mask rotation unit 22 rotates the mask to a desired angle. The mask determination unit 23 determines the type of the conveyed mask. This determination may include a determination as to whether the conveyed mask is a mask of a desired type.

The mask determination unit 23 includes a determination section such as a barcode reader or a quick-response (QR) code® reader and determines the type of the mask by reading an identification mark such as a barcode or a QR code provided on the mask. The position of the identification mark provided on the mask differs depending on the mask. The position of the determination section included in the mask determination unit 23 also differs for each exposure apparatus. Accordingly, the mask rotation unit 22 rotates the mask so that the determination section can read the identification mark on the mask when the mask is conveyed to the mask determination unit 23. For example, when the determination section is configured to read the identification mark located immediately below, the mask rotation unit 22 rotates the mask in advance so that the identification mark on the mask is located immediately below the determination section when the mask is conveyed to the mask determination unit 23. This rotational operation rotates the mask by 180 degrees, for example.

The exposure unit 30 exposes a pattern of the conveyed mask onto the conveyed substrate through the projection optical system.

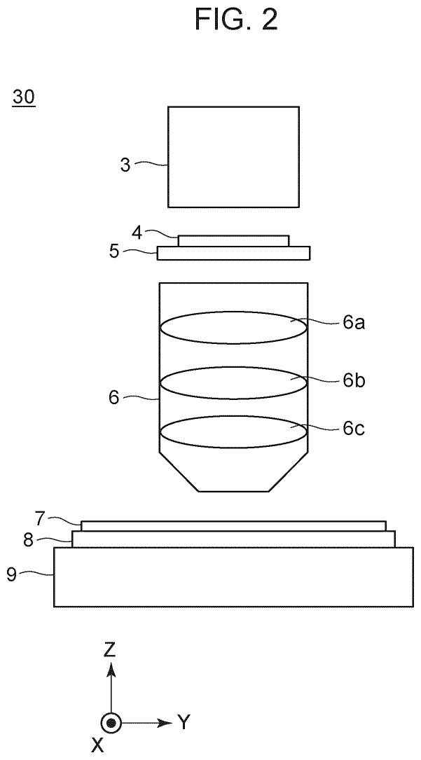

FIG. 2 is a schematic diagram of the exposure unit 30 according to this embodiment. The exposure unit 30 includes an illumination optical system 3 that emits light, a mask stage 5 that holds the mask 4, a projection optical system 6, a substrate chuck 8 that holds the substrate 7, and a substrate stage 9 that is movable with the substrate chuck 8 placed thereon. The mask 4 is, for example, a mask in which a pattern to be transferred (e.g., a circuit pattern) is formed of chromium on the surface of a quartz glass substrate. The substrate 7 is, for example, a monocrystal silicon substrate, on which a photosensitive material (resist) is applied. The projection optical system 6 includes optical elements 6a, 6b, and 6c. Although this embodiment shows an example in which the projection optical system 6 includes three optical elements, the projection optical system 6 may include any number of optical elements.

In the exposure apparatus 1, exposure light from a light source (not shown) illuminates the mask 4 held by the mask stage 5 through the illumination optical system 3. The light transmitted through the mask 4 irradiates the substrate 7 through the projection optical system 6. At this time, the light from a pattern formed on the mask 4 forms an image on the surface of the substrate 7, and a shot region of the substrate 7 (the photosensitive material on the substrate 7) is exposed by the pattern image. The exposure apparatus 1 exposes the shot region on the substrate 7 in this manner and exposes each of the plurality of shot regions.

The control unit 2 controls the components in the exposure apparatus 1. The control unit 2 includes a processing unit, a bus, a read only memory (ROM), a random access memory (RAM), and a storage device. The components function in accordance with programs. The processing unit is a processor that performs computations for control in accordance with a program and controls the individual components connected to the bus. This processing unit may be implemented by a central processing unit (CPU), a programmable logic device (PLD), such as a field-programmable gate array (FPGA), an application-specific integrated circuit (ASIC), a computer incorporating programs, or a combination of all or some of these. The ROM is a data read only memory device, in which programs and data are stored. The RAM is a data read/write memory device, which is used for storing programs and data. The RAM is used to temporarily store data such as results of computations performed by the CPU. The storage device is also used to store programs and data. The storage device is also used as a temporary storage for the programs and data of an operating system (OS) of the control unit 2. The storage device is slower in input/output of data as compared with the RAM, but is capable of storing a large amount of data. The storage device is preferably a non-volatile storage device capable of storing data persistently so that the stored data can be referred to over a long period of time. The storage device is mainly constituted by a magnetic storage device (hard disk drive (HDD)), but may alternatively be a device that performs data reading and writing by loading an external medium such as a compact disc (CD), a digital versatile disc (DVD), or a memory card.

The control unit 2 may be integrally formed with the other parts of the exposure apparatus 1 (in a common casing), or may be separated from the other parts of the exposure apparatus 1 (in a separate casing).

Here, the aberration of the projection optical system 6 changes as an exposure process is performed. In particular, when a specific mask (specific pattern) is continuously exposed, the exposure load on a specific portion of the projection optical system 6 (at a specific rotational angle about the optical axis of the projection optical system 6) increases, thereby causing a significant change in aberration. Specifically, in an optical element included in the projection optical system 6, the temperature of a region irradiated with a large amount of exposure light through the pattern of the mask 4 (at a specific rotational angle about the optical axis of the projection optical system 6) increases. In an optical element included in the projection optical system 6, the temperature of a region where exposure light is blocked by a region of the mask 4 other than an opening and thus not irradiated with the exposure light is unlikely to increase.

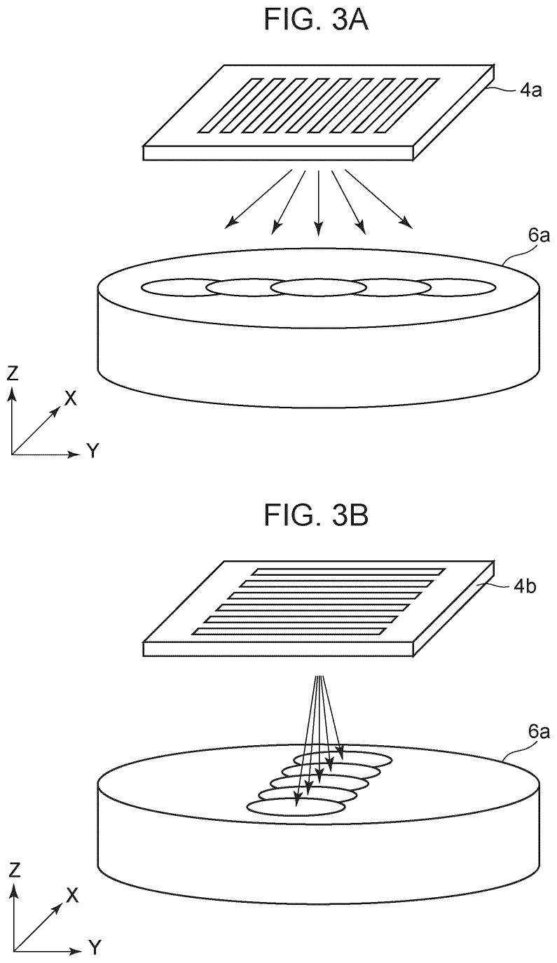

FIGS. 3A and 3B are schematic diagrams illustrating an exposure load on the optical element 6a included in the projection optical system 6 when light is applied to a pattern of the mask 4. In FIGS. 3A and 3B, the mask 4 is illuminated by an effective light source formed by the illumination optical system 3. FIG. 3A is a schematic diagram illustrating an exposure load on the optical element 6a included in the projection optical system 6 when light is applied to a mask 4a having a line-and-space pattern in which a plurality of rectangular patterns extending in the X-axis direction are arranged in the Y-axis direction. In the case of FIG. 3A, light is applied to a region along the Y-axis direction corresponding to the arrangement of the pattern, and the exposure load becomes large in this region. FIG. 3B is a schematic diagram illustrating an exposure load on the optical element 6a included in the projection optical system 6 when light is applied to a mask 4b having a line-and-space pattern in which a plurality of rectangular patterns extending in the Y-axis direction are arranged in the X-axis direction.

In the case of FIG. 3B, light is applied to a region along the X-axis direction corresponding to the arrangement of the pattern, and the exposure load becomes large in this region.

When the aberration of the projection optical system 6 exceeds an allowable value, the exposure accuracy becomes lower than desired exposure accuracy. As a countermeasure, there is a method of suspending the exposure process until the aberration becomes equal to or less than the allowable value; however, this method will decrease a throughput per unit time.

Accordingly, this embodiment provides an exposure apparatus advantageous in terms of throughput. Specifically, the mask 4 is rotated based on information regarding the projection optical system 6. The mask 4 is rotated about the axis (Z-axis) perpendicular to a plane in which a pattern of the mask 4 is formed (the X-Y plane in FIGS. 1 and 2). This enables a specific portion of the projection optical system 6, corresponding to a specific rotational angle about the optical axis of the projection optical system 6 where the exposure load becomes large during exposure processing to be changed. Accordingly, the waiting time required when a method of suspending the exposure process until the aberration becomes equal to or less than an allowable value is employed can be reduced.

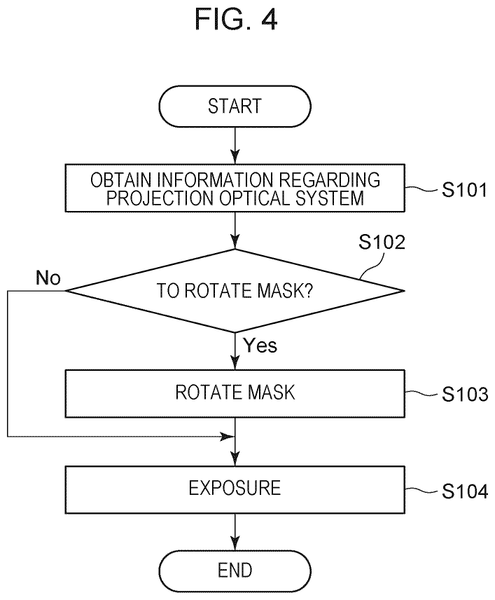

FIG. 4 is a flowchart for rotating the mask 4 based on information regarding the projection optical system 6. First, the control unit 2 obtains information regarding the projection optical system 6 (acquisition step, S101). The information regarding the projection optical system 6 includes, for example, at least one of the measurement result of the aberration of the projection optical system 6, the prediction result of the aberration of the projection optical system 6, the measurement result of the temperature of an optical element included in the projection optical system 6, the accumulated time of the exposure process, and the number of times of the exposure process. The measurement result of the aberration of the projection optical system 6 and the measurement result of the temperature of an optical element included in the projection optical system 6 include measured values.

The current aberration amount of the projection optical system 6 is obtained, for example, by measuring the light intensity received by a sensor disposed on the substrate stage 9 when the substrate stage 9 is driven.

The prediction of the aberration of the projection optical system 6 is performed, for example, based on the measured current aberration amount and information regarding the exposure in the following manufacturing lot (the exposure amount, the number of shots, the scan speed during exposure, a pattern of the mask, etc.). This prediction is obtained, for example, by adding the current aberration amount to a value obtained by multiplying a coefficient of a change amount of the aberration of the projection optical system 6, a coefficient of an aberration amount influenced by the pattern of the mask, an exposure time (which depends on the number of shots and the scan speed), and an exposure amount.

The measurement of the temperature of each optical element included in the projection optical system 6 is performed by disposing temperature sensors at specific angular positions (e.g., every 90 degrees) about the optical axis of the optical element and measuring the temperature at each position of the optical element using the temperature sensor.

The accumulated time of the exposure process is, for example, an accumulated time when a mask having a specific pattern is continuously subjected to exposure processing. The continuous exposure processing includes a case where the exposure is temporarily interrupted, for example, for replacing the substrate, and then immediately resumed.

The number of times of exposure processing refers to, for example, the number of substrates exposed or the number of shot regions when a mask having a specific pattern is continuously subjected to exposure processing.

Next, the control unit 2 determines whether to rotate the mask 4 (determination step, S102). This determination is performed based on the information regarding the projection optical system 6 obtained in step S101. For example, the control unit 2 determines whether a value included in the information regarding the projection optical system 6 exceeds a preset allowable value, and when the value exceeds the allowable value, the control unit 2 determines to rotate the mask 4. The allowable value may be determined as appropriate by the user in accordance with the process. When the determinations are made based on the measurement result of the temperature of an optical element included in the projection optical system 6, the determinations may be made based on a temperature difference between a first position in the optical element and a second position in the optical element different from the first position.

This determination may be made based on the prediction result (predicted value) of the information regarding the projection optical system 6 in the next lot of exposure processing. In other words, this determination may be made based on a predicted value regarding the state of the projection optical system 6 when an exposure process is performed for a single lot. In other words, the determination may be made based on at least one of the prediction result of the aberration of the projection optical system 6, the prediction result of the temperature of an optical element included in the projection optical system 6, a predicted accumulated time of the exposure process, and the number of times the exposure process is to be performed in a next lot of exposure processing. This predicted value itself is also included in the information regarding the projection optical system 6.

In this determination, the angle of rotation of the mask 4 may be determined. The details of the rotational angle of the mask 4 will be described later.

The control unit 2 determines the destination of transfer of the mask 4 based on the determination in step S102. When the mask 4 is to be rotated, the control unit 2 controls the mask transfer unit 21 to convey the mask 4 to the rotation unit, whereas when the mask 4 is not to be rotated, the control unit 2 controls the mask transfer unit 21 to convey the mask 4 to a region where exposure processing is to be performed (exposure unit 30).

If in step S102 it is determined to rotate the mask 4, the mask 4 is rotated (rotation step, S103). If in step S102 the rotational angle of the mask 4 is also determined, the mask 4 is rotated based on the determined angle. In particular, when the rotational angle of the mask 4 has not been determined, the mask 4 is rotated, for example, by a predetermined rotational angle (e.g., 90 degrees or 45 degrees). The rotation of the mask 4 in step S103 is performed by a rotation unit including a rotation mechanism for rotating the mask 4. The rotation unit is, for example, at least one of the mask rotation unit 22, the mask transfer unit 21, and the mask stage 5.

When the substrate 7 already has an underlying pattern (a pattern of a previously exposed lower layer), the position of the underlying pattern and the position of the pattern to be newly exposed (the pattern position of the mask 4) are to be aligned. Accordingly, when the mask 4 is to be rotated, the substrate 7 needs to be rotated in synchronization with the rotation of the mask 4. For example, when the mask 4 is to be rotated by 90 degrees, the substrate 7 is also rotated by 90 degrees. Examples of the substrate rotation unit for rotating the substrate 7 include the substrate transfer unit 11 and the substrate stage 9.

If in step S102 it is determined not to rotate the mask 4, or after the mask 4 has been rotated in step S103, a pattern formed on the mask 4 is exposed on the substrate 7 through the projection optical system 6 (exposure step, S104).

The determination as to whether to rotate the mask 4 according to the flowchart may be performed before exposure processing for one lot, for each substrate, or before exposure processing for a specific number of lots.

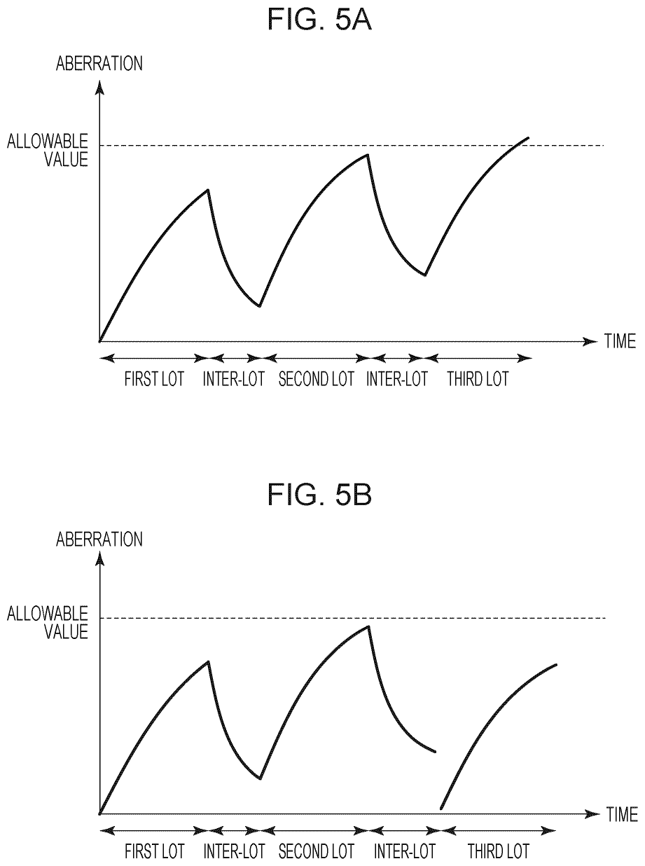

FIGS. 5A and 5B are schematic diagrams of aberration variations in a region of an optical element included in the projection optical system 6 that is used for exposing the substrate 7. FIG. 5A is a diagram illustrating a case where the mask 4 having a specific pattern is continuously exposed without being rotated. Since light is continuously applied to a specific portion of the projection optical system 6 during exposure processing for a lot, the aberration increases. On the other hand, since no light is applied between lots (inter-lot), the aberration that has increased by the exposure processing temporarily decreases. In the example of FIG. 5A, in a first lot and a second lot, the aberration falls within the allowable value, whereas in a third lot, the aberration has exceeded the allowable value.

FIG. 5B is a diagram illustrating a case where the mask 4 having a specific pattern is rotated when being continuously exposed. In the example of FIG. 5B, it is determined whether to rotate the mask 4 between the lots after the second lot according to the flowchart of FIG. 4. Specifically, since the value included in the information regarding the projection optical system 6 exceeds the allowable value in the third lot, it is determined to rotate the mask 4, and the mask 4 is rotated before the exposure processing in the third lot is started. This allows the aberration in a region of an optical element included in the projection optical system 6 that is to be used in exposing the substrate 7 at the start of the third lot to be decreased, preventing the aberration from exceeding the allowable value during the exposure processing in the third lot.

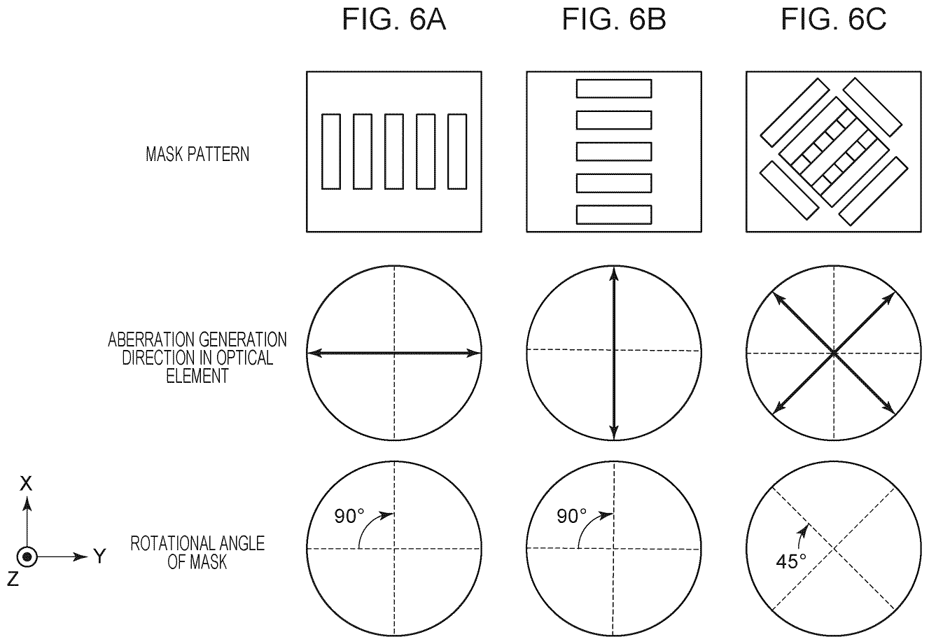

FIGS. 6A to 6C are schematic diagrams illustrating rotational angles when the mask 4 is rotated. FIG. 6A illustrates an example of the mask 4 having a line-and-space pattern in which a plurality of rectangular patterns extending in the X-axis direction are arranged in the Y-axis direction. In this case, the direction in which aberration occurs in an optical element included in the projection optical system 6 is the Y-axis direction. Accordingly, by rotating the mask 4 by 90 degrees, the next exposure processing can be performed in a state where the aberration in a region of an optical element included in the projection optical system 6 that is used for exposing the substrate 7 is reduced. FIG. 6B illustrates an example of the mask 4 having a line-and-space pattern in which a plurality of rectangular patterns extending in the Y-axis direction are arranged in the X-axis direction. In this case, the direction in which aberration occurs in an optical element included in the projection optical system 6 is the X-axis direction. Accordingly, by rotating the mask 4 by 90 degrees, the next exposure processing can be performed in a state where the aberration in a region of an optical element included in the projection optical system 6 that is used for exposing the substrate 7 is reduced. FIG. 6C illustrates an example of the mask 4 having a pattern in which a plurality of rectangular patterns, each inclined with respect to the X-axis and Y-axis directions, are arranged to intersect with one another. In this case, the direction in which aberration occurs in an optical element included in the projection optical system 6 is a direction inclined with respect to the X-axis and Y-axis directions. Accordingly, by rotating the mask 4 by 45 degrees, the next exposure processing can be performed in a state where the aberration in a region of an optical element included in the projection optical system 6 that is used for exposing the substrate 7 is reduced.

Here, a mark formed at the mask 4 that is used to align the mask 4 with the substrate stage 9 may deviate from a desired position (alignment position) by rotating the mask 4. In preparation for such a case, a plurality of marks may be formed on the mask 4 so that the marks of the mask 4 are located at positions where alignment processing can be performed even when the mask 4 is rotated.

According to this embodiment, by rotating the mask 4 based on information regarding the projection optical system 6, a waiting time required when a method of suspending exposure processing until the aberration becomes equal to or less than an allowable value can be reduced, thereby providing an advantage in terms of throughput.

### Second Embodiment

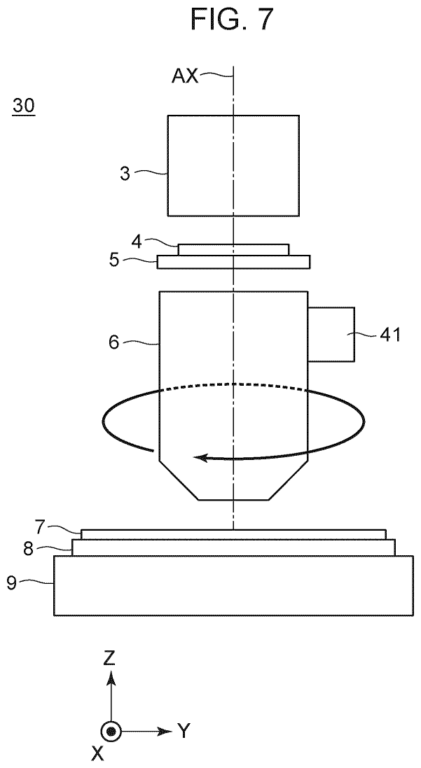

The present embodiment is configured to rotate the projection optical system 6 or an optical element included in the projection optical system 6 based on information regarding the projection optical system 6. FIG. 7 is a schematic diagram of an exposure unit 30 according to this embodiment. An exposure apparatus 1 according to this embodiment includes a rotation unit 41 configured to rotate the projection optical system 6 about the optical axis AX of the projection optical system 6.

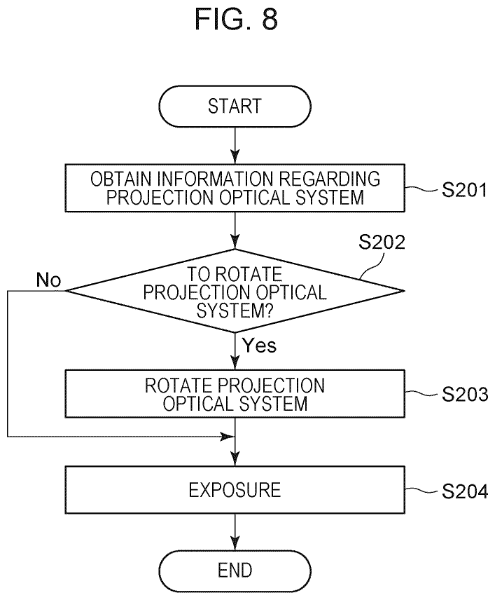

FIG. 8 is a flowchart for rotating the projection optical system 6 based on information regarding the projection optical system 6. First, the control unit 2 obtains information regarding the projection optical system 6 (acquisition step, S201). The information regarding the projection optical system 6 is the same as in the first embodiment. Next, the control unit 2 determines whether to rotate the projection optical system 6 (determination step, S202). This determination is performed based on the information regarding the projection optical system 6 obtained in step S201. For example, the control unit 2 determines whether a value included in the information regarding the projection optical system 6 exceeds a preset allowable value, and when the value exceeds the allowable value, the control unit 2 determines to rotate the projection optical system 6. The allowable value may be determined as appropriate by the user in accordance with the process. When the determinations are made based on the measurement result of the temperature of an optical element included in the projection optical system 6, the determinations may be made based on a temperature difference between a first position in the optical element and a second position in the optical element different from the first position.

This determination may be made based on the prediction result (predicted value) of the information regarding the projection optical system 6 in the next lot of exposure processing. In other words, the determination may be made based on at least one of the prediction result of the aberration of the projection optical system 6, the prediction result of the temperature of an optical element included in the projection optical system 6, a predicted accumulated time of the exposure process, and the number of times the exposure process is to be performed in a next lot of exposure processing. In this determination, the angle of rotation of the projection optical system 6 may be determined. The determination of the rotational angle of the projection optical system 6 is similar to the determination of the rotational angle of the mask 4 in the first embodiment.

If in step S202 it is determined to rotate the projection optical system 6, the projection optical system 6 is rotated (rotation step, S203). If in step S202 the rotational angle of the projection optical system 6 is also determined, the projection optical system 6 is rotated based on the determined angle. In particular, when the rotational angle of the projection optical system 6 has not been determined, the projection optical system 6 is rotated, for example, by a predetermined rotational angle (e.g., 90 degrees). The rotation of the projection optical system 6 in step S203 is performed by the rotation unit 41.

If in step S202 it is determined not to rotate the projection optical system 6, or after the projection optical system 6 has been rotated in step S203, a pattern formed on the mask 4 is exposed on the substrate 7 through the projection optical system 6 (exposure step, S204). The determination as to whether to rotate the projection optical system 6 according to the flowchart may be performed before exposure processing for one lot, for each substrate, or before exposure processing for a specific number of lots.

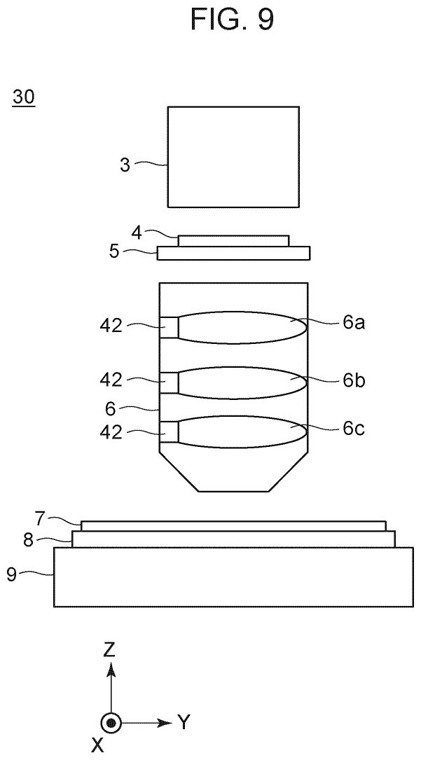

FIG. 9 is a schematic diagram of the exposure unit 30 according to this embodiment. The exposure apparatus 1 of this embodiment includes a rotation unit 42 configured to rotate the optical elements 6a, 6b, and 6c included in the projection optical system 6 about the optical axis AX of the projection optical system 6. Although this embodiment shows an example in which the rotation unit 42 is provided for each of the optical elements 6a, 6b, and 6c, not all of the optical elements 6a, 6b, and 6c included in the projection optical system 6 need be provided with the rotation unit 42, and only a specific optical element may be provided with the rotation unit 42. An example of the specific optical element provided with the rotation unit 42 is an optical element having the largest change in aberration.

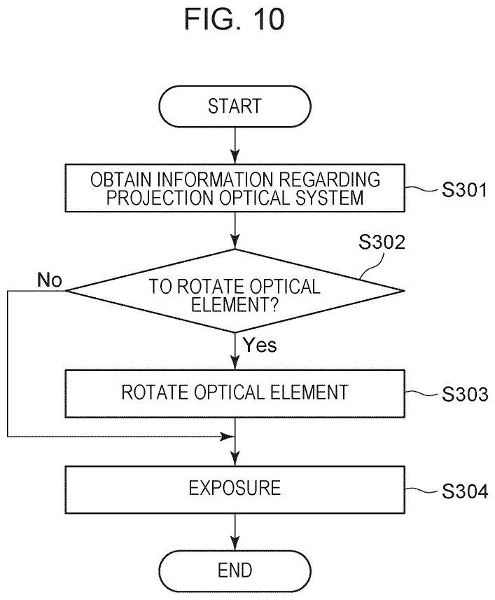

FIG. 10 is a flowchart for rotating an optical element included in the projection optical system 6 based on information regarding the projection optical system 6. First, the control unit 2 obtains information regarding the projection optical system 6 (acquisition step, S301). The information regarding the projection optical system 6 is the same as in the first embodiment. Next, the control unit 2 determines whether to rotate an optical element included in the projection optical system 6 (determination step, S302). This determination is performed based on the information regarding the projection optical system 6 obtained in step S301. For example, the control unit 2 determines whether a value included in the information regarding the projection optical system 6 exceeds a preset allowable value, and when the value exceeds the allowable value, the control unit 2 determines to rotate the optical element. The allowable value may be determined as appropriate by the user in accordance with the process. When the determinations are made based on the measurement result of the temperature of the optical element included in the projection optical system 6, the determinations may be made based on a temperature difference between a first position in the optical element and a second position in the optical element different from the first position.

This determination may be made based on the prediction result of the information regarding the projection optical system 6 in the next lot of exposure processing. In other words, the determination may be made based on at least one of the prediction result of the aberration of the projection optical system 6, the prediction result of the temperature of an optical element included in the projection optical system 6, a predicted accumulated time of the exposure process, and the number of times the exposure process is to be performed in a next lot of exposure processing. In this determination, the angle of rotation of the optical element included in the projection optical system 6 may be determined. The determination of the rotational angle of the optical element included in the projection optical system 6 is similar to the determination of the rotational angle of the mask 4 in the first embodiment. In this determination, among a plurality of optical elements included in the projection optical system 6, the optical element to be rotated may be determined. In other words, even when each of the optical elements 6a, 6b, and 6c is provided with the rotation unit 42, it may be determined that only the optical element 6a is to be rotated.

If in step S302 it is determined to rotate an optical element included in the projection optical system 6, the optical element is rotated (rotation step, S303). If in step S302 the rotational angle of the optical element is also determined, the optical element is rotated based on the determined angle. In particular, when the rotational angle of the optical element has not been determined, the optical element is rotated, for example, by a predetermined rotational angle (e.g., 90 degrees). The rotation of the optical element in step S303 is performed by the rotation unit 42.

If in step S302 it is determined not to rotate the optical element, or after the optical element has been rotated in step S303, a pattern formed on the mask 4 is exposed on the substrate 7 through the projection optical system 6 (exposure step, S304). The determination as to whether to rotate the optical element according to the flowchart may be performed before exposure processing for one lot, for each substrate, or before exposure processing for a specific number of lots.

According to this embodiment, by rotating the projection optical system 6 or an optical element included in the projection optical system 6 based on information regarding the projection optical system 6, a waiting time required when a method of suspending exposure processing until the aberration becomes equal to or less than an allowable value can be reduced, thereby providing an advantage in terms of throughput. Unlike the first embodiment in which the mask 4 is rotated, this embodiment eliminates the need to rotate the substrate 7 in accordance with the rotation of the projection optical system 6 or an optical element included in the projection optical system 6.

### Third Embodiment

The present embodiment relates to a method for manufacturing an article characterized in manufacturing an article using the above-described exposure apparatus.

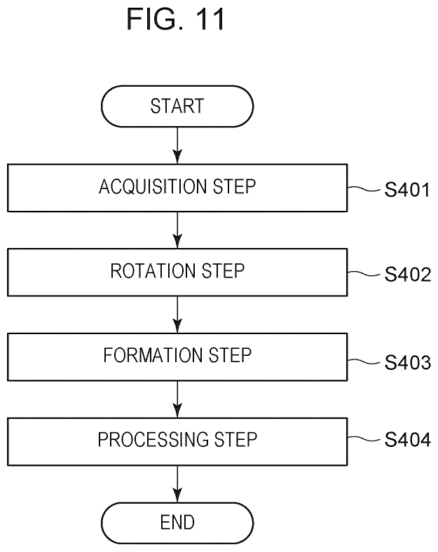

FIG. 11 is a flowchart illustrating a method for manufacturing an article according to this embodiment. After an acquisition step (S401) of obtaining information regarding the projection optical system 6 included in the exposure apparatus 1, a rotation step (S402) is performed to rotate a predetermined member based on the information regarding the projection optical system 6 obtained in the acquisition step. After the rotation step, a formation step (S403) is performed to form a pattern on the substrate 7, and then a processing step (S404) is performed to process the substrate on which the pattern is formed in the formation step.

Examples of articles manufactured by this manufacturing method include semiconductor integrated circuit (IC) devices, liquid crystal display devices, color filters, and microelectromechanical systems (MEMS).

In the formation step, a pattern is formed on a substrate coated with a photosensitive material (such as a silicon wafer or a glass plate) by exposing the substrate with an exposure apparatus (lithography apparatus).

Examples of the processing step include developing a substrate having a pattern formed thereon (photosensitive material), etching and photoresist stripping of the developed substrate, dicing, bonding, and packaging. According to this manufacturing method, articles can be manufactured with a higher throughput per unit time than in the related art.

It is to be understood that the present disclosure is not limited to the above embodiments and that various changes and modifications can be made without departing from the spirit and scope of the present disclosure. Accordingly, the following claims are appended to define the scope of the present disclosure.

According to the present technique, an exposure apparatus advantageous in terms of throughput can be provided.

Embodiment(s) of the present disclosure can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)^{TM}), a flash memory device, a memory card, and the like.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2025-008223, filed Jan. 21, 2025, which is hereby incorporated by reference herein in its entirety.

What is claimed is:

1. An exposure apparatus configured to expose a pattern of a mask onto a substrate, the exposure apparatus comprising:
an illumination optical system configured to illuminate the mask;
a projection optical system configured to project light from the mask onto the substrate;
a rotation unit configured to rotate the mask; and
a control unit configured to control the rotation unit to rotate the mask based on information regarding the projection optical system.

2. The exposure apparatus according to claim 1, wherein the information regarding the projection optical system includes information on an aberration of the projection optical system.

3. The exposure apparatus according to claim 1, wherein the information regarding the projection optical system includes information on a temperature of an optical element included in the projection optical system.

4. The exposure apparatus according to claim 1, wherein the information regarding the projection optical system includes information on an accumulated time during exposure processing.

5. The exposure apparatus according to claim 1, wherein the information regarding the projection optical system includes information on the number of substrates or the number of shot regions that have been subjected to exposure processing.

6. The exposure apparatus according to claim 1,
wherein the information regarding the projection optical system includes information on a measured value regarding a state of the projection optical system, and
wherein the control unit controls the rotation unit to rotate the mask based on the measured value.

7. The exposure apparatus according to claim 1,
wherein the information regarding the projection optical system includes information on a predicted value regarding a state of the projection optical system, and
wherein the control unit controls the rotation unit to rotate the mask based on the predicted value.

8. The exposure apparatus according to claim 7, wherein the predicted value is a predicted value regarding the state of the projection optical system when exposure processing is performed for a single lot.

9. The exposure apparatus according to claim 1, wherein the control unit rotates the mask when a value included in the information regarding the projection optical system exceeds a preset allowable value.

10. The exposure apparatus according to claim 1, further comprising:
a mask transfer unit configured to convey the mask,
wherein, when the mask is to be rotated, the control unit controls the mask transfer unit to convey the mask to the rotation unit, and when the mask is not to be rotated, the control unit controls the mask transfer unit to convey the mask to an exposure processing region.

11. The exposure apparatus according to claim 1, wherein the control unit controls the rotation unit to rotate the mask by 45 degrees or 90 degrees.

12. The exposure apparatus according to claim 1, wherein the control unit determines a rotational angle of the mask and controls the rotation unit to rotate the mask based on the determined angle.

13. The exposure apparatus according to claim 1, further comprising:
a substrate rotation unit configured to rotate the substrate,
wherein the control unit controls the substrate rotation unit to rotate the substrate in accordance with the rotation of the mask.

14. The exposure apparatus according to claim 1, wherein the rotation unit comprises at least one of a mask stage configured to hold the mask during exposure processing, a mask transfer unit including a hand configured to hold the mask, and a mask rotation unit configured to rotate the mask before the mask is conveyed to the mask stage.

15. An exposure apparatus configured to expose a pattern of a mask onto a substrate, the exposure apparatus comprising:
an illumination optical system configured to illuminate the mask;
a projection optical system configured to project light from the mask onto the substrate;
a rotation unit configured to rotate the projection optical system or an optical element included in the projection optical system; and
a control unit configured to control the rotation unit to rotate the projection optical system or an optical element included in the projection optical system based on information regarding the projection optical system.

16. An exposure method for exposing a pattern of a mask onto a substrate through a projection optical system, the method comprising:
acquiring information regarding the projection optical system;
rotating, based on the information regarding the projection optical system, at least one of the mask, the projection optical system, and an optical element included in the projection optical system; and
exposing the substrate after the rotation.

17. A method for manufacturing an article, the method comprising:
acquiring information regarding a projection optical system included in an exposure apparatus:
rotating a predetermined member based on the information, acquired in the acquisition, regarding the projection optical system;
after the rotation, forming a pattern on the substrate by transferring a pattern of a mask to the substrate through the projection optical system; and
processing the substrate on which the pattern is formed in the formation.

18. The method for manufacturing an article according to claim 17, wherein the predetermined member comprises any one of the mask, the projection optical system, and an optical element included in the projection optical system.
